(19) United States
(12) Patent Application Publication
(10) Pub. No.: US 2015/0372430 A1
(43) Pub. Date: Dec. 24, 2015

(54) Bypassable Light Responsive Power Cord Device

(71) Applicant: Nathan Foster, Bristow, VA (US)

(72) Inventor: Nathan Foster, Bristow, VA (US)

(21) Appl. No.: 14/308,839

(22) Filed: Jun. 19, 2014

(51) Int. Cl. H01R 13/70; H03K 17/78; H01R 25/00

(52) U.S. Cl. CPC H01R 13/70; H01R 25/003; H03K 17/78

(57) ABSTRACT

A bypassable light responsive power cord device activates electrically powered items responsive to a light sensor which may be bypassed allowing the device to act as a conventional power cord. The device includes an electrical cord, a plug coupled to a first end of the electrical cord, and an electrical outlet electrically coupled to a second end of the electrical cord. A light sensor is coupled to the electrical cord and a sensor switch is coupled to the light sensor. The sensor switch is electrically coupled between the first end of the electrical cord and the second end of the electrical cord such that the sensor switch is open when light is detected by the light sensor. A bypass switch is electrically coupled to the electrical cord in parallel to the sensor switch to circumvent the sensor switch and deliver electrical current to the electrical outlet.

### BACKGROUND OF THE DISCLOSURE

### Field of the Disclosure

The disclosure relates to power cord devices and more particularly pertains to a new power cord device for activating electrically powered items responsive to a light sensor which may be bypassed allowing the device to act as a conventional power cord.

### SUMMARY OF THE DISCLOSURE

An embodiment of the disclosure meets the needs presented above by generally comprising an electrical cord, a plug coupled to a first end of the electrical cord, and an electrical outlet electrically coupled to a second end of the electrical cord. A light sensor is coupled to the electrical cord and a sensor switch is coupled to the light sensor. The sensor switch is electrically coupled between the first end of the electrical cord and the second end of the electrical cord such that the sensor switch is open when light is detected by the light sensor. A bypass switch is electrically coupled to the electrical cord in parallel to the sensor switch to circumvent the sensor switch and deliver electrical current to the electrical outlet.

There has thus been outlined, rather broadly, the more important features of the disclosure in order that the detailed description thereof that follows may be better understood, and in order that the present contribution to the art may be better appreciated. There are additional features of the disclosure that will be described hereinafter and which will form the subject matter of the claims appended hereto.

The objects of the disclosure, along with the various features of novelty which characterize the disclosure, are pointed out with particularity in the claims annexed to and forming a part of this disclosure.

### BRIEF DESCRIPTION OF THE DRAWINGS

The disclosure will be better understood and objects other than those set forth above will become apparent when consideration is given to the following detailed description thereof. Such description makes reference to the annexed drawings wherein:

FIG. 1 is a top front side perspective view of a bypassable light responsive power cord device according to an embodiment of the disclosure.

FIG. 2 is a partial top view of an embodiment of the disclosure.

FIG. 3 is a partial side view of an embodiment of the disclosure.

FIG. 4 is a partial bottom view of an embodiment of the disclosure.

FIG. 5 is a schematic view of an embodiment of the disclosure.

### DESCRIPTION OF THE PREFERRED EMBODIMENT

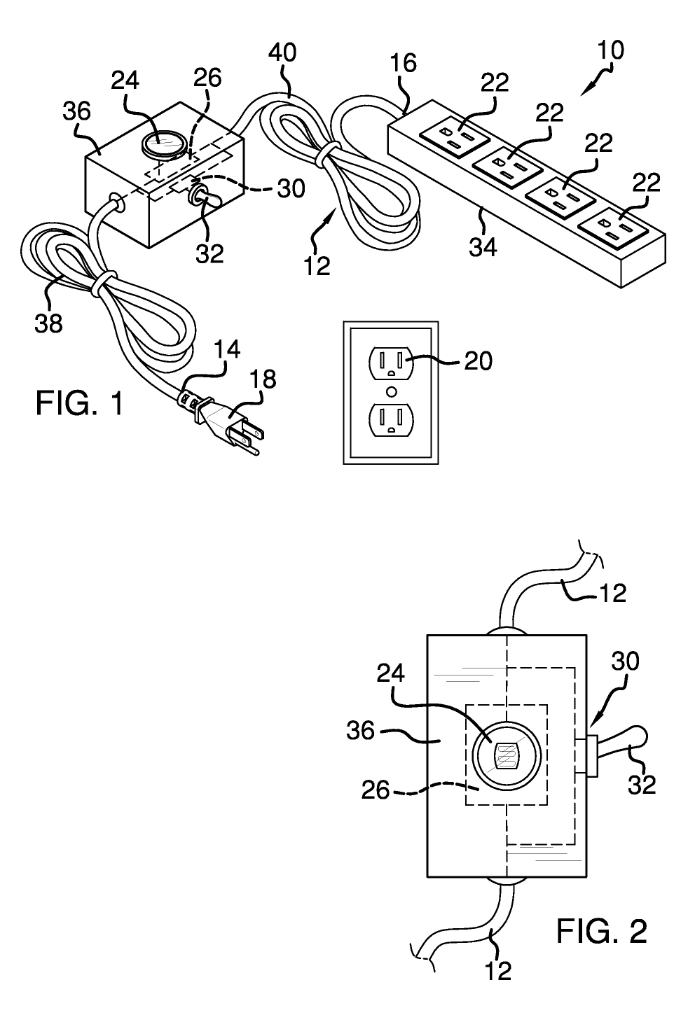

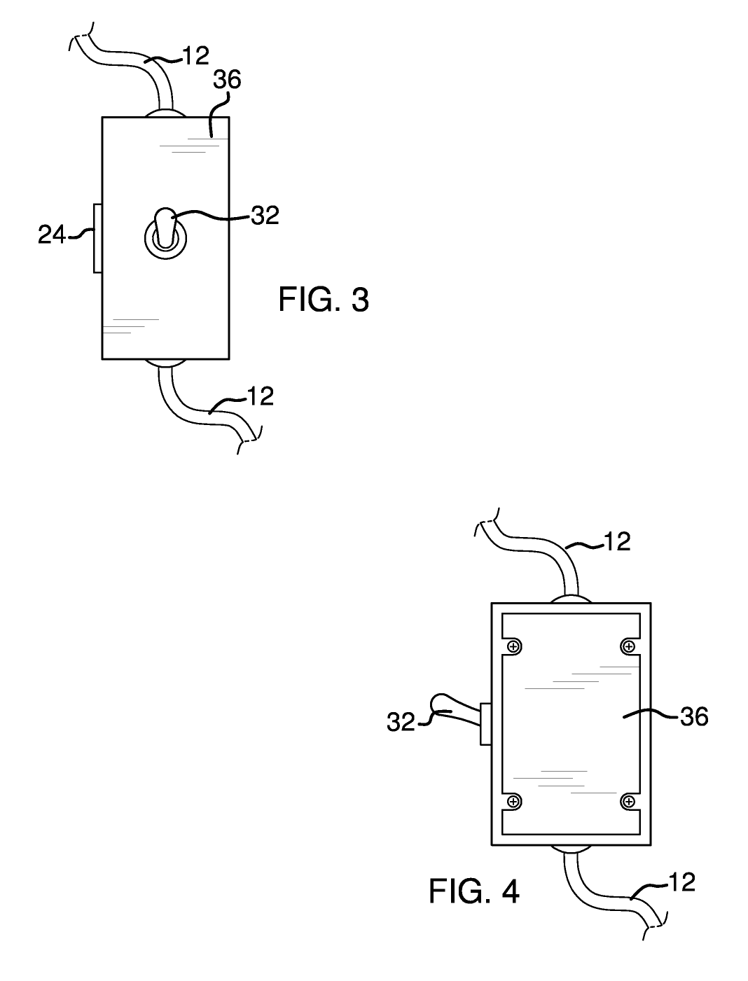

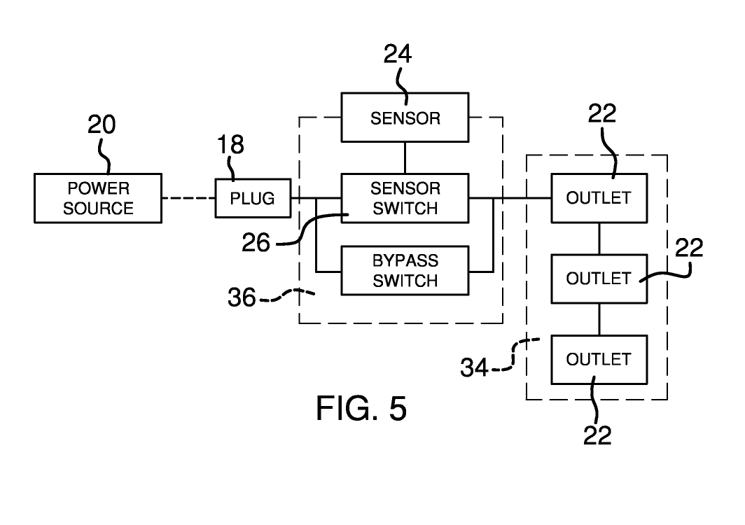

With reference now to the drawings, and in particular to FIGS. 1 through 5 thereof, a new power cord device embodying the principles and concepts of an embodiment of the disclosure and generally designated by the reference numeral 10 will be described.

As best illustrated in FIGS. 1 through 5, the bypassable light responsive power cord device 10 generally comprises an electrical cord 12 having a first end 14 and a second end 16. A plug 18 is coupled to the first end 14 of the electrical cord 12 wherein the electrical cord 12 is configured for coupling to an electrical power source 20. At least one electrical outlet 22 is electrically coupled to the second end 16 of the electrical cord 12 wherein the electrical outlet 22 is configured to provide electrical power to an extrinsic electrical apparatus such as a light, radio, or the like. A light sensor 24 is coupled to the electrical cord 12. A sensor switch 26 coupled to the light sensor 24. The sensor switch 26 is electrically coupled between the first end 14 of the electrical cord 12 and the second end 16 of the electrical cord 12. The sensor switch 26 is open when light is detected by the light sensor 24 wherein the sensor switch 26 prevents electrical current from being carried to the electrical outlet 22.

A bypass switch 30 is electrically coupled to the electrical cord 12 in parallel to the sensor switch 26 wherein closing the bypass switch 30 circumvents the sensor switch 26 to deliver electrical current to the electrical outlet 22 regardless of the position of the sensor switch 26. The bypass switch 30 is a toggle switch 32 or the like.

A main housing 34 is coupled to the second end 16 of the electrical cord 12. The electrical outlet 22 is coupled to the main housing 34. The electrical outlet 22 may be one of a plurality of electrical outlets 22 coupled to the main housing 34 in a conventional arrangement. Each of the electrical outlets 22 is electrically coupled to the electrical cord 12.

A sensor housing 36 is coupled to the electrical cord 12 between a first section 38 of the electrical cord 12 and a second section 40 of the electrical cord 12 allowing positioning of the sensor housing 36 in a desired location away from the main housing 34. The light sensor 24 and the sensor switch 26 are each coupled to and positioned in the sensor housing 36. The bypass switch 30 is coupled to and positioned in the sensor housing 36.

In use, electrical devices are plugged into the electrical outlets 22 in a conventional manner. The main housing 34 may be positioned as desired to obscure view of the main housing 34, electrical outlets 22 and associated cords of the electrical devices. The sensor housing 36 is positioned to allow the light sensor 24 to detect low light levels wherein the sensor switch 26 closes. Thus, the electrical devices plugged into the electrical outlets 22 will be powered during low light conditions. The user may also manipulate the bypass switch 30 to allow flow of electricity to the electrical outlets 22 despite the positioning of the sensor switch 26. Thus, the light sensor 24 is effectively bypassed and the device 10 may be used as a conventional power strip when desired.

With respect to the above description then, it is to be realized that the optimum dimensional relationships for the parts of an embodiment enabled by the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by an embodiment of the disclosure.

Therefore, the foregoing is considered as illustrative only of the principles of the disclosure. Further, since numerous modifications and changes will readily occur to those skilled in the art, it is not desired to limit the disclosure to the exact construction and operation shown and described, and accordingly, all suitable modifications and equivalents may be resorted to, falling within the scope of the disclosure.

I claim:

1. A bypassable light responsive power cord device comprising:
an electrical cord having a first end and a second end;
a plug coupled to said first end of said electrical cord wherein said electrical cord is configured for coupling to an electrical power source;
an electrical outlet electrically coupled to a second end of said electrical cord wherein said electrical outlet is configured to provide electrical power to an extrinsic electrical apparatus;
a light sensor coupled to said electrical cord;
a sensor switch coupled to said light sensor, said sensor switch being electrically coupled between said first end of said electrical cord and said second end of said electrical cord, said sensor switch being open when light is detected by said light sensor wherein sensor switch prevents electrical current from being carried to said electrical outlet; and
a bypass switch electrically coupled to said electrical cord in parallel to said sensor switch wherein closing said bypass switch circumvents said sensor switch to deliver electrical current to said electrical outlet.

2. The device of claim 1, further comprising a main housing coupled to said second end of said electrical cord, said electrical outlet being coupled to said main housing.

3. The device of claim 1, further comprising said electrical outlet being one of a plurality of electrical outlets coupled to said main housing, each of said electrical outlets being electrically coupled to said electrical cord.

4. The device of claim 1, further comprising a sensor housing coupled to said electrical cord between a first section of said electrical cord and a second section of said electrical cord, said light sensor and said sensor switch each being coupled to and positioned in said sensor housing.

5. The device of claim 4, further comprising said bypass switch being coupled to and positioned in said sensor housing.

6. The device of claim 1, further comprising said bypass switch being a toggle switch.

7. A bypassable light responsive power cord device comprising:
an electrical cord having a first end and a second end;
a plug coupled to said first end of said electrical cord wherein said electrical cord is configured for coupling to an electrical power source;
an electrical outlet electrically coupled to a second end of said electrical cord wherein said electrical outlet is configured to provide electrical power to an extrinsic electrical apparatus;
a light sensor coupled to said electrical cord;
a sensor switch coupled to said light sensor, said sensor switch being electrically coupled between said first end of said electrical cord and said second end of said electrical cord, said sensor switch being open when light is detected by said light sensor wherein sensor switch prevents electrical current from being carried to said electrical outlet;
a bypass switch electrically coupled to said electrical cord in parallel to said sensor switch wherein closing said bypass switch circumvents said sensor switch to deliver electrical current to said electrical outlet, said bypass switch being a toggle switch;
a main housing coupled to said second end of said electrical cord, said electrical outlet being coupled to said main housing, said electrical outlet being one of a plurality of electrical outlets coupled to said main housing, each of said electrical outlets being electrically coupled to said electrical cord; and
a sensor housing coupled to said electrical cord between a first section of said electrical cord and a second section of said electrical cord, said light sensor and said sensor switch each being coupled to and positioned in said sensor housing, said bypass switch being coupled to and positioned in said sensor housing.
